(19) United States
(12) Patent Application Publication
(10) Pub. No.: US 2014/0146454 A1
(43) Pub. Date: May 29, 2014

(54) Electrostatic Capacitance Type Touch Panel and Anti-Glare Film

(71) Applicant: Kazuhiro Nozawa, Saitama (JP)

(72) Inventor: Kazuhiro Nozawa, Saitama (JP)

(73) Assignee: KIMOTO CO., LTD., Tokyo (JP)

(21) Appl. No.: 14/232,276

(22) PCT Filed: Jun. 18, 2012
(86) PCT No.: PCT/JP2012/065476

§ 371 Date: Jan. 12, 2014

(30) Foreign Application Priority Data
Jul. 26, 2011 (JP) 2011-162883

(51) Int. Cl. G02B 1/11; H05K 7/00; H03K 17/96

(52) U.S. Cl. CPC G02B 1/11; H03K 17/962; H05K 7/00
USPC 361/679.01; 200/600; 359/601

(57) ABSTRACT

Provided is an electrostatic capacitance type touch panel (4) having an operating surface that is provided with anti-glare properties and low visibility of fingerprints. A textured surface satisfying all of the following conditions ‘a’ to ‘d’ is provided on the operating surface side of the electrostatic capacitance type touch panel (4). Condition ‘a’: Ra (arithmetic mean roughness) of 0.1-0.5 μm. Condition ‘b’: RΔq (root-mean-square gradient) of 2° or greater. Condition ‘c’: Rsm (mean spacing between profile peaks) of 0.1 mm or less. Condition ‘d’: Rp (maximum peak height) of 1.0 μm or less. All of these values are measured in accordance with JIS B0601:2001.

### TECHNICAL FIELD

The present invention relates to an electrostatic capacitance type touch panel having anti-glare properties. The present invention also relates to an anti-glare film used for a film adhered to a surface of a variety of devices and a film for other touch panels, etc.

### BACKGROUND ART

A transparent film for surface protection is often adhered to a surface of a variety of devices (liquid crystal display devices, showcases and cover glasses of clocks and instruments, etc.).

In recent years, as typified by ATMs of banks and ticket vending machines, electronic devices provided with a touch panel type liquid crystal monitor have been increasing. As a surface protection transparent film of such liquid crystal monitors and a transparent film used for touch panels, anti-glare films are used, on which a surface texture treatment is performed to prevent difficulty in seeing caused by glare due to reflections of external lights.

To enhance the anti-glare effect of an anti-glare film, a degree of roughness of the textured surface may be increased. However, when touching an electronic device provided with an anti-glare film with a higher roughness degree on the textured surface as such, there was a tendency that adhered fingerprints become noticeable. This is because a part of the textured surface touched by a hand is buried with fingerprint components, a haze becomes low on the portion buried with the fingerprint components and a haze difference arises comparing with a haze on other portions.

Although to roughen a surface of an anti-glare film is necessary to develop anti-glare properties as explained above, fingerprints to be adhered by touching tend to become noticeable. Therefore, it has been difficult to satisfy both of the anti-glare properties and an effect of obscuring fingerprints (low visibility of fingerprints) only by simply roughening the surface of the anti-glare film. Due to this, also as to touch panels having a surface provided with an anti-glare film as above, it has been difficult to satisfy anti-glare properties and the low visibility of fingerprints at the same time.

As an anti-glare film, which solves the problem relating to fingerprints by roughening a surface thereof, those having a wet tension of 25 mN/m or greater on the surface of a mat film may be mentioned (Patent Article 1). The anti-glare film of the patent document 1 has an improved fingerprint wipe-off performance (fingerprint erasing properties) as a result of making fingerprints a very thin film to be easily spread to a wide area.

### RELATED ART DOCUMENTS

### Patent Documents

Patent Document 1: International publication No. 2004/046230

### SUMMARY OF THE DISCLOSED SUBJECT MATTER

The anti-glare film of the patent document 1 has improved fingerprint erasable properties as a result of bringing it conform easily with fingerprint components, and it was not exactly for preventing adhesion of fingerprints. Therefore, before wiping off the fingerprints, the adhered fingerprints were easily noted and it was not something that satisfies low visibility of fingerprints.

As explained above, electronic devices having a surface provided with an anti-glare film of the related art could not make fingerprints adhered when touched by hands less noticeable. Particularly, electrostatic capacitance type touch panels on the increase in recent years are operated with fingers in a complicated way, so that there have been demands for remediation for the problem of fingerprints being noticeable.

As an aspect of the present invention, there is provided an electrostatic capacitance type touch panel having an operating surface provided with anti-glare properties and low visibility of fingerprints. As another aspect of the present invention, there is provided an anti-glare film provided with low visibility of fingerprints.

The present inventors found that, at the point when a finger touches an electrostatic capacitance type touch panel, there was not a big difference in an adhesion amount of fingerprints regardless of difference of films to be placed on the touch panel. On the other hand, in an operation of running a finger across a display device surface (enlarging or shrinking operation of an image, etc.), they found that an adhesion amount of fingerprints became different depending on difference of films to be placed on the touch panel.

The inventors furthermore studied, consequently found it possible to suppress an adhesion amount of fingerprints and to make fingerprints less noticeable as well as providing anti-glare properties (namely, both of anti-glare properties and low visibility of fingerprints can be attained), and completed the present invention.

An electrostatic capacitance type touch panel of the present invention has a textured surface, which satisfies all of the conditions ‘a’ to ‘d’ below, on an operating surface side. A method of obtaining a surface with a predetermined texture is not particularly limited and may be attained by placing an anti-glare film of the present invention on the operating surface side. Alternatively, it may be attained by providing the operating surface side with a predetermined textured surface obtained by etching a glass. Furthermore, it can be also attained by performing a processing of giving a texture directly on the operating surface.

An anti-glare film of the present invention is characterized by having a textured surface satisfying all of conditions ‘a’ to ‘d’ below.

A display device of the present invention is characterized by being configured by arranging an anti-glare film of the present invention on a screen.

Condition ‘a’: Ra (arithmetic mean roughness) is 0.1 to 0.5 μm,

Condition ‘b’: RΔq (root-mean-square gradient) is 2° or greater,

Condition ‘c’: Rsm (mean spacing between profile peaks) is 0.1 mm or less, and

Condition ‘d’: Rp (maximum peak height) is 1.0 μm or less.

(note that all of the values are measured in accordance with JIS B0601:2001)

The present invention includes the following modes.

(1) The electrostatic capacitance type touch panel can be configured by arranging the anti-glare film of the present invention on the operating surface side.
(2) On a surface with a texture formed thereon satisfying all of the conditions ‘a’ to ‘d’ above, a contact angle of pure water may be adjusted to 100° or greater.
(3) The textured surface may be adjusted to furthermore satisfy at least one of the condition ‘e’ and condition ‘f’ below in addition to the conditions ‘a’ to ‘d’ above.

Condition ‘e’: Rzjis (ten-point mean roughness) is 2.0 μm or less, and

Condition ‘f’: Ry (maximum height) is 1.5 μm or less.

(note that all of the values are measured in accordance with JIS B0601:2001)

(4) A haze value of the anti-glare film of the present invention measured in accordance with JIS K7136:2000 may be adjusted to 5% or greater and 30% or less.
(5) The anti-glare film of the present invention may comprise an anti-glare layer provided with a specific textured surface as explained above. In that case, the specific anti-glare layer may be obtained by molding by using a mold and coating of a particle-containing paint, etc. When using a particle-containing paint, it may be configured so as to satisfy the following relationships.

Average particle diameter (D) of particles: 2.0 μm or greater and 4.0 μm or less, and

Thickness of anti-glare layer: 170% or greater and 210% or less of (D).

The electrostatic capacitance type touch panel of the present invention is provided with a surface properties of specific conditions on its operating surface side, therefore, both of anti-glare properties and low visibility of fingerprints can be attained. Namely, according to the present invention, it is possible to provide an electrostatic capacitance type touch panel having an operating surface provided with anti-glare properties and low visibility of fingerprints.

The anti-glare film of the present invention has surface properties of specific conditions, therefore, low visibility of fingerprints can be realized without undermining anti-glare properties. Namely, according to the present invention, it is possible to provide an anti-glare film having low visibility of fingerprints suitably arranged, for example, on an operating surface, etc. of an electrostatic capacitance type touch panel.

The display device of the present invention has an anti-glare film having surface properties of specific conditions on a screen, therefore, both of anti-glare properties and low visibility of fingerprints can be attained. Namely, according to the present invention, it is also possible to provide a display device having a display screen having anti-glare properties and low visibility of fingerprints.

### BRIEF DESCRIPTIONS OF DRAWINGS

FIG. 1 is a sectional view showing an example of an anti-glare film of the present invention.

FIG. 2 is a sectional view showing another example of an anti-glare film of the present invention.

FIG. 3 is a sectional view showing an example of a display device of the present invention.

FIG. 4 is a sectional view showing an example of an electrostatic capacitance type touch panel of the present invention.

FIG. 5 is a sectional view showing another example of an electrostatic capacitance type touch panel of the present invention.

### DESCRIPTION OF NUMERICAL NOTATIONS

1 and 1a . . . anti-glare film, 11 . . . transparent substrate, 12 . . . anti-glare layer, 2 . . . display device, 21 . . . display element, 22 . . . protection plate, 23 . . . touch panel, 4 and 4a . . . electrostatic capacitance type touch panel, 41 . . . transparent substrate, 42 . . . transparent conductive layer, 43 . . . protective layer, 44 . . . electromagnetic wave shielding layer, 45 . . . extraction electrode line

### EXEMPLARY MODE FOR CARRYING OUT THE DISCLOSED SUBJECT MATTER

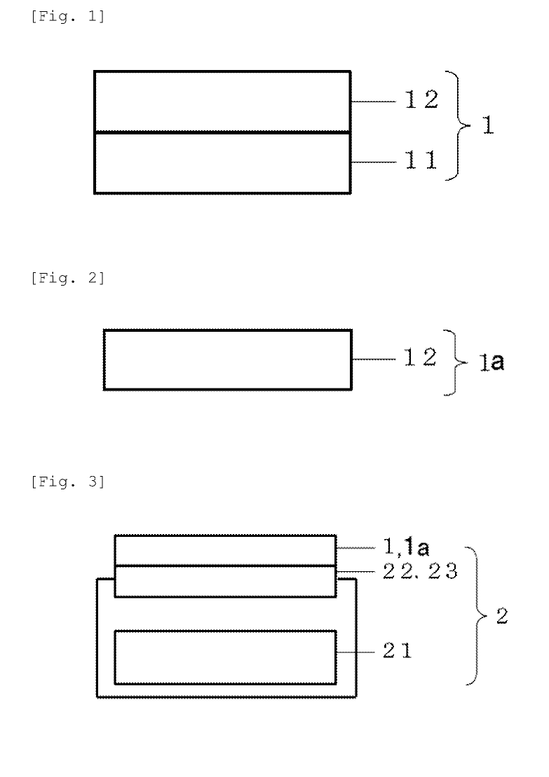

First, an explanation will be made on an example of the anti-glare film of the present invention. As shown in FIG. 1, an anti-glare film of the present example is an example of a multilayer structure, wherein an anti-glare layer 12 is stacked on a transparent substrate 11. Note that the anti-glare film of the present invention is not limited to the multilayer structure in FIG. 1 and, for example, as shown in FIG. 2, an anti-glare film 1a may be configured by a single-layer anti-glare layer 12 in the case where it can be handled by itself.

As the transparent substrate 11, transparent films formed by materials, such as polyethylene terephthalate, polybutylene terephthalate, polyethylene naphthalate, polycarbonate, polyethylene, polypropylene, polystyrene, triacetyl cellulose and acryl, may be mentioned. Among them, a uniaxially-stretched and particularly biaxially-stretched polyethylene terephthalate film is preferable on the point of being excellent in mechanical strength and dimension stability. Also, those having improved adhesiveness with an anti-glare layer 12 as a result of performing a corona discharge treatment or providing an easily adhesive layer on the surface of the transparent substrate 11 may be also suitably used. A thickness of the transparent substrate 11 is generally 25 to 500 μm and preferably 50 to 200 μm.

Surface properties of the anti-glare layer 12 is adjusted properly. Specifically, an arithmetic mean roughness, a root-mean-square gradient, a mean spacing between profile peaks and the maximum peak height on the surface of the anti-glare layer 12 are adjusted to be in predetermined ranges.

Ra (arithmetic mean roughness) is a parameter indicating an average of roughness curves.

Rp (maximum peak height) is a parameter indicating the maximum value of peak heights of roughness curves in a reference length.

In the present invention, the reason why the Ra and Rp are selected as control parameters is because a point was found through experiments that fat components of fingerprints can become hard to be removed from fingers when moving fingers for operation as a result of controlling these parameters.

The RΔq (root-mean-square gradient) indicates a root-mean-square of a local gradient dz/dx in a standard length and is a parameter as an indication of a gradient degree of a roughness curve. The larger the RΔq value is, the sharper the roughness curve is, while the gradient of the roughness curve becomes milder as the RΔq value becomes smaller.

The Rsm (mean spacing between profile peaks) indicates an average of lengths of contour curve elements in a reference length, and is a parameter as an indication of intervals of peaks and depths.

In the present invention, the reason why the RΔq and Rsm are selected as control parameters is because the point was found through experiments that an contact area of fingers can become small even when moving fingers for operation as a result of controlling these parameters.

In the present example, surface properties of the anti-glare layer 12 are adjusted so as to satisfy all of the conditions ‘a’ to ‘d’ (the condition ‘a’, condition ‘b’, condition ‘c’ and condition ‘d’).

The condition ‘a’ is a condition that the Ra value becomes to be in a predetermined range, specifically, 0.1 μm or more and 0.5 μm or less. Preferably, it is 0.4 μm or less and more preferably 0.2 μm or less.

The condition ‘b’ is a condition that the RΔq value becomes a predetermined value or more, specifically, 2° or greater, preferably about 10° or less and more preferably about 6° or less.

The condition ‘c’ is a condition that the Rsm value becomes a predetermined value or less, specifically, 0.1 mm or less. It is preferably 0.07 mm or less and more preferably 0.05 mm or less. Also preferably it is 0.02 mm or more.

The condition ‘d’ is a condition that the Rp value becomes a predetermined value or less, specifically, 1.0 μm or less and preferably 0.9 μm or less. Also, it is preferably about 0.6 μm or more.

By setting Ra to be 0.1 μm or more in the condition ‘a’, anti-glare properties can be developed. While, to prevent exceedingly roughening the surface by setting Ra in the condition ‘a’ to be 0.5 μm or less and Rp in the condition ‘d’ to be 1.0 μm or less, it becomes possible to make it harder for fat components of fingerprints to be removed from the fingers when moving fingers for operation. Particularly by setting Ra to be 0.4 μm or less, it becomes possible to make it harder for fat components of fingers to be removed from the fingers.

Note that by setting Ra to be 0.5 μm or less, it is also possible to prevent difficulty in viewing the display screen.

By setting RΔq in the condition ‘b’ to be 2° and Rsm in the condition ‘c’ to be 0.1 mm or less, it is possible to make the surface of the anti-glare layer 12 to have a shape of dense sharp protrusions so as to be able to decrease an area of fingers touching the surface of the anti-glare layer 12.

By setting Rsm in the condition ‘c’ to be 0.07 mm or less, it is possible to decrease an area of fingers touching the anti-glare film.

By setting Rp in the condition ‘d’ to be 0.9 μm or less, it becomes possible to make it harder for fat components of fingerprints to be removed from the fingers.

In the present invention, as explained above, when moving fingers for operation, due to a synergic action of a technical idea of making it hard for fat components of fingerprints to be removed from fingers (Ra and Rp) and a technical idea of decreasing a finger contact area (RΔq and Rsm), it becomes possible to suppress an adhesion amount of fingerprints and to make fingerprints less noticeable (attainment of low visibility of fingerprints) even after the operation of moving fingers in a complicated way on the anti-glare film.

In the present example, in addition to the four parameters explained above, it is preferable that at least one of ten-point mean roughness and maximum height is adjusted to be in a predetermined range. As same as Ra, Rzjis (ten-point mean roughness) and Ry (maximum height) are parameters to indicate a texture on the surface of the anti-glare layer 12.

Specifically, in the present example, it is preferable that surface properties of the anti-glare layer 12 are adjusted to satisfy at least one of the condition ‘e’ and condition ‘f’ as well as the conditions ‘a’ to ‘d’ above.

The condition ‘e’ is a condition that a value of Rzjis is a predetermined value or less, specifically, 2.0 μm or less. It is preferably 1.5 μm or less, more preferably 1.0 μm or less and preferably about 0.5 μm or more.

The condition ‘f’ is a condition that a value of Ry is a predetermined value or less, specifically, 1.5 μm or less. It is preferably 1.3 μm or less.

By setting Rzjis in the condition ‘e’ to be 2.0 μm or less, it becomes possible to make fat components of fingerprints hard to be removed from the finger.

To set Ry in the condition ‘f’ to be 1.5 μm or less, it becomes possible to make fat components of fingerprints hard to be removed from fingers.

Note that as to all of Ra, RΔq, Rsm, Rp, Rzjis and Ry, the values are measured by methods in accordance with JIS B0601:2001 and measured, for example, by a contact-type surface roughness measurement device (SURFCOM 1500SD2-3DF: TOKYO SEIMITSU CO., LTD.).

In the present example, a haze value of an entire anti-glare film 1 or 1a including the anti-glare layer 12 is adjusted to preferably 5% or greater, more preferably 10% or greater and preferably 30% or less and more preferably 25% or less. Note that a haze value in this example is a value measured in accordance with JIS K7136:2000.

When the haze of the entire film 1 or 1a is adjusted to 5% or greater, anti-glare properties can be more preferable. When a haze value of the entire film 1 or 1a is adjusted to 30% or less, it is possible to prevent difficulty in seeing a display screen.

In this example, a thickness of the anti-glare layer 12 is preferably 3 μm or more, more preferably 4 μm or more, furthermore preferably 5 μm or more and preferably 9 μm or less, more preferably 8 μm or less and furthermore preferably 7 μm or less.

The anti-glare layer 12 having the surface properties (textured surface) explained above may be obtained, for example, by molding by using a mold and coating of a particle-containing paint. Other than that, means like etching and embossing are effective, as well.

In the case of molding by using a mold, it can be manufactured by producing a mold in a complementary shape of the textured surface, pouring materials to compose the anti-glare layer 12, such as a polymer resin, to the mold and curing, then, taking it out from the mold. In the case of using a transparent substrate 11, it can be manufactured by pouring a polymer resin, etc. into a mold, stacking the transparent substrate 11 thereon, then, curing the polymer resin, etc. and removing it together with the transparent substrate 11 from the mold.

A method of producing the mold having a complementary shape of the textured surface is not particularly limited and, for example, a means of forming a texture meeting at least the conditions ‘a’ to ‘d’ on a plain plate by using a laser microfabrication technique and using this as a male mold to produce a mold (female mold) for molding may be mentioned.

In the case of coating a particle-containing paint, it can be formed by applying an anti-glare layer application liquid containing particles and a binder resin to a transparent substrate 11 and drying.

As the particles, inorganic particles (for example, silica, alumina, talc, clay, calcium carbonate, magnesium carbonate, barium sulfate, aluminum hydroxide, titanium dioxide and zirconium oxide, etc.) and resin particles (for example, acrylic-type resin particles, silicone-type resin particles, nylon-type resin particles, styrene-type resin particles, polyethylene-type resin particles, benzoguanamine-type resin particles, urethane-type resin particles, etc.) may be mentioned. Among them, particles with a specific weight of less than 2.0 g/cm³ are preferable for giving a high RΔq value. Particularly, silica with a specific weight of less than 2.0 g/cm³ is preferable.

An average particle diameter (D) of particles is preferably 2.0 to 4.0 μm. A content of the particles in the anti-glare layer 12 is preferably 7 to 10 parts by weight with respect to 100 parts by weight of a binder resin. Furthermore, it is preferable that a thickness of the anti-glare layer 12 is 170 to 210% of an average particle diameter (D) of the particles. By satisfying these conditions, using particles having a specific weight of less than 2.0 g/cm³ and using as a binder an organic-inorganic hybrid ionizing radiation curable resin, it becomes possible to easily satisfy the conditions ‘a’ to ‘d’ explained above.

Note that an average particle diameter and a coefficient of variation of a particle diameter distribution of the resin particles in the present invention are values measured by Coulter counter method.

Coulter counter method is a method of electrically measuring the number and size of particles dispersed in a solution, wherein particles are dispersed in an electrolytic solution and, during letting the particles pass through fine holes, on which electricity flows, by using an attractive force, the electrolytic solution exactly in a volume of the particles is replaced so as to increase resistance and voltage pulses being proportional to the volume of the particles is measured. Therefore, by electrically measuring the height and volume of the voltage pulses, the number of particles and respective particle volumes are measured so as to obtain particle diameters and a particle diameter distribution.

A coefficient of variation (CV value) is a value indicating a disperse state of a particle diameter distribution, and is a percentage of a value obtained by dividing a standard deviation of a particle diameter distribution (square root of unbiased estimate of variance) with an arithmetic average value of particle diameters (average particle diameter). Namely, it indicates how much a spread of the particle diameter distribution (variation of particle diameters) is with respect to an average value (arithmetic average diameter) and it is normally obtained as a CV value (no unit)=(standard variation/average value). The smaller the CV value is, the narrower the particle size distribution becomes (sharp), and the larger the value is, the broader the particle size distribution becomes (broad).

As a binder resin component of the anti-glare layer 12, a thermoplastic resin, thermosetting resin, ionizing radiation curable type may be mentioned. Among them, in terms of abrasion resistance, a thermosetting type resin or ionizing radiation curable type are preferable. In terms of being easily able to obtain the surface shape as explained above, an ionizing radiation curable type resin is preferable.

As a thermosetting type resin, melamine-type, phenol-type and urethane-type resins, etc. may be mentioned.

As an ionizing radiation curable type resin, a photopolymeric prepolymer, which can be crosslinking cured by irradiation of an ionizing radiation (ultraviolet ray or electron ray), may be used. As the photopolymeric prepolymer, an acrylic-type prepolymer, which has two or more acryloyl groups in one molecule and becomes a three-dimensional reticulate structure when crosslinking cured, is particularly preferably used. As the acrylic-type prepolymer, urethane acrylate, polyester acrylate, epoxy acrylate, melamine acrylate, polyfluoroalkyl acrylate, silicone acrylate, etc. may be used. Furthermore, these acrylic-type prepolymers may be used alone, however, it is preferable to add a photopolymeric monomer to improve crosslinking curable property and to improve hardness of the anti-glare layer 12.

As a photopolymeric monomer, one or more kinds selected from 2-ethylhexyl acrylate, 2-hydroxyethyl acrylate, 2-hydroxypropyl acrylate, butoxyethyl acrylate and other mono-functional acryl monomers; 1,6-hexanediol diacrylate, neopentyl glycol diacrylate, diethylene glycol diacrylate, polyethylene glycol diacrylate, hydroxypivalic acid ester neopentyl glycol diacrylate and other bifunctional acryl monomers; dipentaerythritol hexacrylate, trimethylpropane triacrylate, pentaerythritol triacrylate and other multifunctional acryl monomers; etc. may be used.

As an ionizing radiation curable type resin, other than the above-mentioned photopolymeric prepolymers and photopolymeric monomers, in the case of curing by using ultraviolet ray irradiation, an additive like a photopolymerization initiator and photopolymerization accelerator, etc. may be preferably used. As a photopolymerization initiator, acetophenone, benzophenone, Michler's ketone, benzoin, benzylmethylketal, benzoylbenzoate, α-acyloxime ester, thioxanthones, etc. may be mentioned. A photopolymerization accelerator is capable of accelerating a curing speed by reducing a polymerization hindrance by an air during curing and, for example, p-dimethylamino benzoate isoamyl ester and p-dimethylamino benzoate ethyl ester, etc. may be mentioned.

As an ionizing radiation curable type resin, an ionizing radiation curable type organic-inorganic hybrid resin is also preferably used. An ionizing radiation curable type organic-inorganic hybrid resin gives an effect of making particles buoyant in the anti-glare layer 12 so as to be able to heighten RΔq.

Note that an ionizing radiation curable type organic-inorganic hybrid resin is different from a traditional complex typified by glass fiber reinforced plastic (FRP), and wherein organic and inorganic are closely mixed, the dispersion state is at a molecular level or close to that, and irradiation of an ionizing radiation brings a reaction between inorganic components and organic components, so that a coating can be formed. As an inorganic component of an ionizing radiation curable type organic-inorganic hybrid resin as such, silica, titania and other metal oxides may be mentioned, and those using silica is preferable among them.

The anti-glare layer 12 has a pencil hardness of preferably H or more based on JIS-K5400:1990 in terms of preventing scars, more preferably 2H or more and furthermore preferably 3H or more.

Also, a contact angle of pure water on the anti-glare layer 12 surface is preferably 100° or greater. When the contact angle of pure water is 100° or greater, fingerprint components can be repelled easily and it is possible to prevent fingerprints from becoming noticeable due to a haze difference as a result of burying the textured surface with fingerprint components. Namely, when the contact angle of pure water on the anti-glare layer 12 surface is 100° or greater, even a small amount of adhered fingerprints can be made less noticeable, so that the effects of the present invention (explained above) can be furthermore enhanced.

To increase the contact angle of pure water on the anti-glare layer 12 surface, it is preferable to include a fluorinated or silicone-type resin and additives in the anti-glare layer 12.

The anti-glare layer 12 may be formed by applying a composition containing binder resin components and particles as explained above for composing the anti-glare layer 12 to a transparent substrate 11, drying and, in accordance with need, curing (irradiating ionizing radiation or heating).

The anti-glare film 1 or 1a of the present example has the anti-glare layer 12 having surface properties of specific conditions as explained above, therefore, while maintaining the anti-glare properties, it makes it possible for fat components of fingerprints to be hardly removed from fingers, and a contact area of the fingers can be decreased. Namely, it can attain low visibility of fingerprints while not undermining the anti-glare properties.

The anti-glare film 1 or 1a of the present example may be used by being arranged on a screen of a variety of display devices (for example, liquid crystal display devices, CRT display devises, plasma display devices and EL display devices, etc.) and on posters and other displays, showcases, and cover glasses of watches, clocks and instruments, etc.

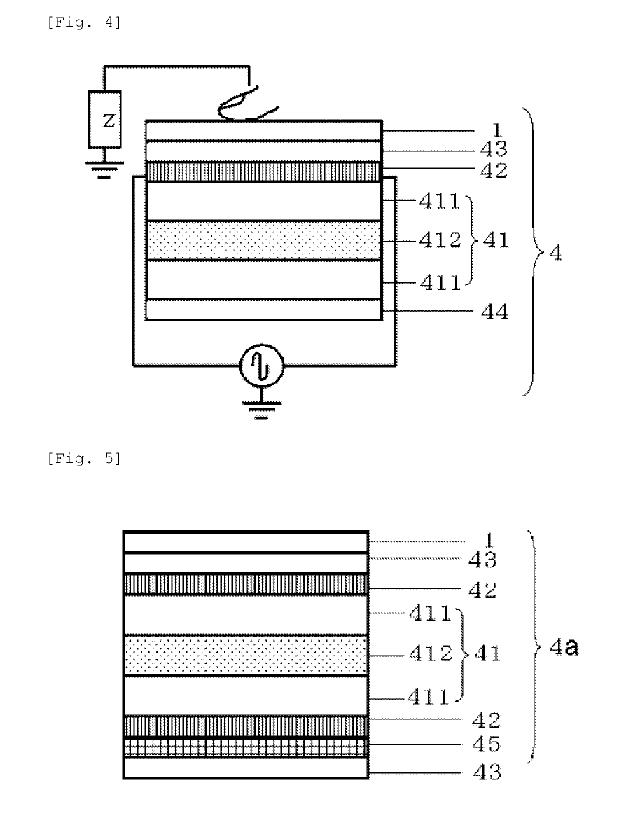

The anti-glare film 1 or 1a of the present example may be, as shown in FIG. 3, also arranged on a screen of a display device 2 (a protection plate 22 provided on a display element 21) and on a screen of the display device 2 (a resistance film type touch panel or electrostatic capacitance type touch panel 23 mounted on the display element 21), as well.

Next, an explanation will be made on an example of an electrostatic capacitance type touch panel of the present invention. Note that electrostatic capacitance type touch panel may be generally divided to a surface capacitive type and a projected capacitive type.

An electrostatic capacitance type touch panel 4 of the present example is, as shown in FIG. 4, an example of a surface capacitive type and comprises a transparent conductive layer 42, a protective layer 43 and an anti-glare film 1 (or 1a: it will be the same below) of the present example on one surface of a transparent substrate 41 obtained by bonding two transparent substrates 411 with an adhesive agent 412. On the other surface of the transparent substrate 41, a multilayer body comprising an electromagnetic wave shielding layer 44 is connected to a basic circuit.

The basic circuit uses a sine wave as a drive signal, and a constant voltage circuit is commonly used, wherein an extremely weak current is supplied to four corners of the transparent conductive layer 42 at the same time. Almost no current flows on the panel when not touched by human because it has same potentials at four corners, but when a finger touches on one point, a current flowing on the panel changes due to a human body capacitance. A current change amount at that time is inversely proportional to a distance from the four corners to the touched point. Then, the current is converted to a voltage so as to determine coordinates.

An electrostatic capacitance type touch panel 4a in another embodiment is an example of a projected capacitive type as shown in FIG. 5 and comprises a transparent conductive layer 42, protective layer 43 and anti-glare film 1 on one surface of a transparent substrate 41 obtained by bonding two transparent substrates 411 with an adhesive agent 412. It is configured to have a transparent conductive layer 42, extraction electrode line 45 and protective layer 43 on the other surface of the transparent substrate 41.

In a projected capacitive electrostatic capacitance type touch panel 4a, one transparent conductive layer 42 is formed by an X electrode for recognizing the X coordinate and the other transparent conductive layer 42 is formed by a Y electrode for recognizing the Y coordinate. The coordinates of the touched point is detected by a voltage change between the X-Y electrodes generated by an approach of a finger and determined based thereon.

Note that in both of the example in FIG. 4 (surface capacitive type) and the example in FIG. 5 (projected capacitive type), a protective layer 43 and an anti-glare film 1 are provided successively on a transparent conductive layer 42, however, it may be also configured that the protective layer 43 is omitted and the anti-glare film 1 also functions as a protective layer 43. Alternatively, it may be configured to have a not shown protection plate (a glass substrate or a plastic substrate) on the protective layer 43 and have an anti-glare film 1 on the protection plate. Note that an inorganic thin film, such as silica, is preferable as the protective layer 43.

Since the electrostatic capacitance type touch panel 4 or 4a of the present example has a textured surface having a specific shape on an operating surface side, it has anti-glare properties and it is possible to make fingerprints less noticeable even when operating with fingers in a complicated way.

Note that, in the embodiment explained above, an explanation was made as an example on the configuration of providing the anti-glare film 1 (or 1a) of the present example so that a textured surface thereof (anti-glare layer 12 side) comes to the operating surface side, however, the present invention is not limited to this configuration. It is not to exclude other examples, such as the configuration of providing the operating surface of the touch panel 4 or 4a with a glass having a predetermined textured surface formed by etching.

### EXAMPLES

Below, furthermore detailed explanations will be made on examples given by specifying the embodiments of the present invention. Note that “part” and “%” in the examples are based on weight unless otherwise mentioned.

### Example 1

On one surface of a transparent polyester film having a thickness of 125 μm (COSMOSHINE A4350), an anti-glare layer application liquid ‘a’ of the prescription below was applied, dried and irradiated with an ultraviolet ray so as to form an anti-glare layer having a thickness of 6 μm, so that an anti-glare film of the example 1 was obtained.

### <Anti-Glare Layer Application Liquid ‘a’>

ionizing radiation curable type resin composition 200 parts
(DeSolite 7501: JSR Corporation, Solid content 50%)
   photopolymerization initiator 1 part
(IRGACURE 651: Ciba Japan K. K.)
   silica 8.5 parts
(OK-500: DEGUSSA CORP)
(average particle diameter: 3.0 μm, specific weight: 1.9)
   diluting solution 200 parts

### Example 2

Other than forming an anti-glare layer having a thickness of 5 μm by changing the application condition, an anti-glare film of an example 2 was obtained in the same way as in the example 1.

### Comparative Example 1

Other than changing the anti-glare layer application liquid ‘a’ to an anti-glare layer application liquid ‘b’ below, an anti-glare film of a comparative example 1 was obtained in the same way as in the example 1.

### <Anti-Glare Layer Application Liquid ‘b’>

ionizing radiation curable type resin composition 200 parts
(DeSolite 7501: JSR Corporation, Solid content 50%)
   photopolymerization initiator 1 part
(IRGACURE 651: Ciba Japan K. K.)
   silica 6.5 parts
(OK-520: DEGUSSA CORP)
(average particle diameter: 3.0 μm, specific weight: 2.0)
   diluting solution 200 parts

### Comparative Example 2

Other than changing the anti-glare layer application liquid ‘a’ to an anti-glare layer application liquid ‘c’ below and changing the thickness of the anti-glare layer to 2.5 μm, an anti-glare film of a comparative example 2 was obtained in the same way as in the example 1.

### <Anti-Glare Layer Application Liquid ‘c’>

ionizing radiation curable type resin composition
(solid content 80%) 125 parts
(UNIDIC 17-813: DIC Corporation)
   photopolymerization initiator 1 part
(IRGACURE 651: Ciba Japan K. K.)
   acryl resin particles 0.5 part
(Ganz Pearl GM-0105: Ganz Chemical Co.)
(average particle diameter: 2.3 μm)
   diluting solution 200 parts

### Comparative Example 3

Other than changing the anti-glare layer application liquid ‘a’ to an anti-glare layer application liquid ‘d’ below and changing the thickness of the anti-glare layer to 6.8 μm, an anti-glare film of a comparative example 3 was obtained in the same way as in the example 1.

### <Anti-Glare Layer Application Liquid ‘d’>

ionizing radiation curable type resin composition
(solid content 80%) 125 parts
(UNIDIC 17-813: DIC Corporation)
   photopolymerization initiator 1 part
(IRGACURE 651: Ciba Japan K. K.)
   silica 4.5 parts
(OK-500: DEGUSSA CORP)
(average particle diameter: 3.0 μm, specific weight: 1.9)
   diluting solution 200 parts

### Comparative Example 4

Other than changing the anti-glare layer application liquid ‘a’ to an anti-glare layer application liquid ‘e’ below and changing the thickness of the anti-glare layer to 5.1 μm, an anti-glare film of a comparative example 4 was obtained in the same way as in the example 1.

### <Anti-Glare Layer Application Liquid ‘e’>

ionizing radiation curable type resin composition
(solid content 80%) 125 parts
(UNIDIC 17-813: DIC Corporation)
   photopolymerization initiator 1 part
(IRGACURE 651: Ciba Japan K. K.)
   silica 5.5 parts
(OK-412: DEGUSSA CORP)
(average particle diameter: 3.0 μm, specific weight: 1.9)
   diluting solution 200 parts

### Comparative Example 5

Other than changing the anti-glare layer application liquid ‘a’ to an anti-glare layer application liquid ‘f’ below and changing the thickness of the anti-glare layer to 3.6 μm, an anti-glare film of a comparative example 5 was obtained in the same way as in the example 1.

### <Anti-Glare Layer Application Liquid ‘f’>

ionizing radiation curable type resin composition
(solid content 80%) 125 parts
(UNIDIC 17-813: DIC Corporation)
   photopolymerization initiator 1 part
(IRGACURE 651: Ciba Japan K. K.)
   acryl resin particles 1.5 parts
(MX-500KS: Soken Chemical Engineering Co., Ltd.)
(average particle diameter: 5.0 μm)
   diluting solution 200 parts

### Comparative Example 6

Other than changing the anti-glare layer application liquid ‘a’ to an anti-glare layer application liquid ‘g’ below and changing the thickness of the anti-glare layer to 4.7 μm, an anti-glare film of a comparative example 6 was obtained in the same way as in the example 1.

### <Anti-Glare Layer Application Liquid ‘g’>

ionizing radiation curable type resin composition
(solid content 80%) 125 parts
(UNIDIC 17-813: DIC Corporation)
   photopolymerization initiator 1 part
(IRGACURE 651: Ciba Japan K. K.)
   silica 7.5 parts
(OK-500: DEGUSSA CORP)
(average particle diameter: 3.0 μm, specific weight: 1.9)
   diluting solution 200 parts

[Surface Shape Measurement]

On each of the anti-glare films obtained in the respective examples, a shape of the surface of the anti-glare layers was measured under the condition below by using a contact-type surface roughness measurement apparatus (SURFCOM 1500SD2-3DF: Tokyo Seimitsu Co., Ltd.). Average values of ten-point measurements are shown in Table 1.

### <Measurement Condition>

stylus tip radius: 2 μm, taper angle of stylus tip: 60 degrees, measurement force: 0.75 mN, cutoff value λc: 0.8 mm, measurement rate: 0.6 mm/s

[Haze]

On each of the anti-glare films obtained in the respective examples, a haze was measured by using a turbidimeter (NDH2000: NIPPON DENSHOKU INDUSTRIES Co., Ltd.) in accordance with JIS K7136:2000. The results are shown in Table 1.

[Evaluation]

The following evaluations were made on the anti-glare films obtained in the respective examples. The results are shown in Table 1.

1. Visibility of Display Screen

Each of the anti-glare films was stuck to the touch panel operating surface side of a mobile device (iPod: Apple Inc.) provided with an electrostatic capacitance type touch panel and observation on the display screen was made visually. The results were indicated as “◯” for those with preferable visibility on the display surface and “Δ” for those exhibited hardness in visibility because the display screen was a little whitish.

2. Visibility of Fingerprints

Each of the anti-glare films was stuck to the touch panel operating surface side of a mobile device (iPod: Apple Inc.) provided with an electrostatic capacitance type touch panel and, after operating by moving fingers on the anti-glare film, observation of fingerprint noticeability was made visually. The results were indicated as “◯” for those with not noticeable fingerprints, “Δ” for those with a little noticeable fingerprints and “X” for those with noticeable fingerprints.

3. Anti-Glare Properties

Each anti-glare film was placed with its anti-glare layer facing upward on a black ground below a three band fluorescent lamp and reflection of the fluorescent was evaluated visually. The results were indicated as “◯” for those with no lamp contour of the fluorescent reflected thereon and “Δ” for those with a little reflection of the contour.

TABLE 1

| | | | | | | | | Visibility | Visibility | Anti- |
|---|---|---|---|---|---|---|---|---|---|---|
| | Ra | RΔq | Rsm | Rp | Rzjis | Ry | Haze | on | of | Glare |
| | (μm) | (°) | (mm) | (μm) | (μm) | (μm) | (%) | Screen | Fingerprints | Properties |
| Example 1 | 0.15 | 2.37 | 0.039 | 0.82 | 0.92 | 1.23 | 18.0 | ∘ | ∘ | ∘ |
| Example 2 | 0.14 | 2.18 | 0.048 | 0.70 | 1.21 | 1.07 | 17.0 | ∘ | ∘ | ∘ |
| Comparative | 0.12 | 1.27 | 0.054 | 0.69 | 0.69 | 0.91 | 8.0 | ∘ | x | Δ |
| Example 1 | | | | | | | | | | |
| Comparative | 0.18 | 1.39 | 0.099 | 1.15 | 0.98 | 1.45 | 3.3 | ∘ | x | Δ |
| Example 2 | | | | | | | | | | |
| Comparative | 0.22 | 1.67 | 0.112 | 1.58 | 1.23 | 2.00 | 6.5 | ∘ | x | ∘ |
| Example 3 | | | | | | | | | | |
| Comparative | 0.26 | 2.26 | 0.094 | 1.52 | 1.49 | 2.05 | 10.5 | ∘ | x | ∘ |
| Example 4 | | | | | | | | | | |
| Comparative | 0.39 | 2.18 | 0.111 | 1.10 | 1.84 | 2.13 | 10.0 | ∘ | x | ∘ |
| Example 5 | | | | | | | | | | |
| Comparative | 0.31 | 3.95 | 0.046 | 1.76 | 1.86 | 2.41 | 32.0 | x | Δ | ∘ |
| Example 6 | | | | | | | | | | |

Those in the example 1 had Ra, RΔq, Rsm and Rp satisfying the conditions ‘a’ to ‘d’ of the present invention, therefore, exhibited preferable visibility on the screen, low visibility of fingerprints and excellent anti-glare properties.

Those in the example 2 had Ra, RΔq, Rsm and Rp satisfying the conditions ‘a’ to ‘d’ of the present invention and exhibited preferable visibility on the screen, low visibility of fingerprints and excellent anti-glare properties. However, since Rzjis was 0.92 in the example 1 and 1.21 in the example 2, visibility of fingerprints was more preferable in the example 1 comparing with that in the example 2.

Note that those in the examples 1 and 2 had a contact angle of pure water of 100° or greater on the anti-glare layer surface in all cases. Therefore, fingerprint components were repelled easily and it was possible to prevent fingerprints from becoming noticeable because of a haze difference caused as a result that the textured surface is buried with fingerprint components.

Those in the comparative example 1 had Ra, Rsm and Rp satisfying the conditions of the present invention, however, since RΔq was small, a finger contact area became large, an adhesion amount of fingerprints increased and fingerprints became noticeable.

Those in the comparative example 2 had Ra and Rsm satisfying the conditions of the present invention. However, small RΔq led to an increase of a finger contact area and large Rp resulted in taking fat components of fingerprints easily. Therefore, fingerprints were easily adhered and noticeable.

Those in the comparative example 3 had Ra satisfying the conditions of the present invention. However, small RΔq and large Rsm led to an increase of a finger contact area and large Rp resulted in taking fat components of fingerprints easily. Therefore, fingerprints were easily adhered and noticeable.

Those in the comparative example 4 had Ra, RΔq and Rsm satisfying the conditions of the present invention. However, since Rp was large, fat components of fingerprints were easily taken from the fingers, and the fingerprints were noticeable.

Those in the comparative example 5 had Ra and RΔq satisfying the conditions of the present invention. However, large Rsm led to an increase of a finger contact area and large Rp resulted in taking fat components of fingerprints easily. Therefore, the fingerprints were easily adhered and noticeable.

Those in the comparative example 6 had Ra, RΔq and Rsm satisfying the conditions of the present invention. However, large Rp resulted in taking fat components of fingerprints easily and the fingerprints were noticeable. Note that the reason why fingerprints were less noticeable comparing with those in other comparative examples is considered that the surface is very rough, so that fat components of fingerprints are taken in a short distance and an adhesion area of fingerprints becomes small.

1. An electrostatic capacitance type touch panel having a textured surface, which satisfies all of conditions ‘a’ to ‘d’ below, on an operating surface side.
Condition ‘a’: Ra (arithmetic mean roughness) is 0.1 to 0.5 μm,
Condition ‘b’: RΔq (root-mean-square gradient) is 2° or greater,
Condition ‘c’: Rsm (mean spacing between profile peaks) is 0.1 mm or less, and
Condition ‘d’: Rp (maximum peak height) is 1.0 μm or less.

2. The electrostatic capacitance type touch panel according to claim 1, wherein an anti-glare film having an textured surface satisfying the conditions ‘a’ to ‘d’ is provided on the operating surface side.

3. The electrostatic capacitance type touch panel according to claim 1, wherein a plane of the textured surface formed thereon has a contact angle of pure water adjusted to be 100° or greater.

4. The electrostatic capacitance type touch panel according to claim 1, wherein the textured surface furthermore satisfies at least one of a condition ‘e’ and condition ‘f’ below.
Condition ‘e’: Rzjis (ten-point mean roughness) is 2.0 μm or less, and
Condition ‘f’: Ry (maximum height) is 1.5 μm or less.

5. An anti-glare film having a textured surface satisfying all of conditions ‘a’ to ‘d’ below.
Condition ‘a’: Ra (arithmetic mean roughness) is 0.1 to 0.5 μm,
Condition ‘b’: RΔq (root-mean-square gradient) is 2° or greater,
Condition ‘c’: Rsm (mean spacing between profile peaks) is 0.1 mm or less, and
Condition ‘d’: Rp (maximum peak height) is 1.0 μm or less.

6. The anti-glare film according to claim 5, wherein a plane of the textured surface has a contact angle of pure water adjusted to be 100° or greater.

7. The anti-glare film according to claim 5, wherein the textured surface furthermore satisfies at least one of a condition ‘e’ and condition ‘f’ below.
Condition ‘e’: Rzjis (ten-point mean roughness) is 2.0 μm or less, and
Condition ‘f’: Ry (maximum height) is 1.5 μm or less.

8. The anti-glare film according to claim 5, wherein a haze vale measured in accordance with JIS K7136:2000 is adjusted to be 5% or greater and 30% or less.

9. The anti-glare film according to claim 5, characterized by comprising an anti-glare layer configured by applying a particle-containing paint to a transparent substrate and drying, and satisfying relationships below in the case where the textured surface is formed on the anti-glare layer:
Average particle diameter (D) of particles: 2.0 μm or greater and 4.0 μm or less, and
thickness of anti-glare layer: 170% or greater and 210% or less of (D).

10. A display device configured by arranging an anti-glare film according to claim 5 on a screen.

11. The electrostatic capacitance type touch panel according to claim 2, wherein the textured surface furthermore satisfies at least one of a condition ‘e’ and condition ‘f’ below.
Condition ‘e’: Rzjis (ten-point mean roughness) is 2.0 μm or less, and
Condition ‘f’: Ry (maximum height) is 1.5 μm or less.

12. The electrostatic capacitance type touch panel according to claim 3, wherein the textured surface furthermore satisfies at least one of a condition ‘e’ and condition ‘f’ below.
Condition ‘e’: Rzjis (ten-point mean roughness) is 2.0 μm or less, and
Condition ‘f’: Ry (maximum height) is 1.5 μm or less.

13. The anti-glare film according to claim 6, wherein the textured surface furthermore satisfies at least one of a condition ‘e’ and condition ‘f’ below.
Condition ‘e’: Rzjis (ten-point mean roughness) is 2.0 μm or less, and
Condition ‘f’: Ry (maximum height) is 1.5 μm or less.

14. The anti-glare film according to claim 6, wherein a haze value measured in accordance with JIS K7136:2000 is adjusted to be 5% or greater and 30% or less.

15. The anti-glare film according to claim 7, wherein a haze value measured in accordance with JIS K7136:2000 is adjusted to be 5% or greater and 30% or less.

16. The anti-glare film according to claim 6, characterized by comprising an anti-glare layer configured by applying a particle-containing paint to a transparent substrate and drying, and satisfying relationships below in the case where the textured surface is formed on the anti-glare layer:
Average particle diameter (D) of particles: 2.0 μm or greater and 4.0 μm or less, and thickness of anti-glare layer: 170% or greater and 210% or less of (D).

17. The anti-glare film according to claim 7, characterized by comprising an anti-glare layer configured by applying a particle-containing paint to a transparent substrate and drying, and satisfying relationships below in the case where the textured surface is formed on the anti-glare layer:
Average particle diameter (D) of particles: 2.0 μm or greater and 4.0 μm or less, and thickness of anti-glare layer: 170% or greater and 210% or less of (D).

18. The anti-glare film according to claim 8, characterized by comprising an anti-glare layer configured by applying a particle-containing paint to a transparent substrate and drying, and satisfying relationships below in the case where the textured surface is formed on the anti-glare layer:
Average particle diameter (D) of particles: 2.0 μm or greater and 4.0 μm or less, and thickness of anti-glare layer: 170% or greater and 210% or less of (D).

19. A display device configured by arranging an anti-glare film according to claim 6 on a screen.

20. A display device configured by arranging an anti-glare film according to claim 7 on a screen.
